(19) United States
(12) Patent Application Publication
(10) Pub. No.: US 2024/0371897 A1
(43) Pub. Date: Nov. 7, 2024

(54) IMAGE SENSING DEVICE AND METHOD FOR MANUFACTURING THE SAME

(71) Applicant: SK hynix Inc., Icheon-si (KR)

(72) Inventor: Dong Ha KIM, Icheon-si (KR)

(21) Appl. No.: 18/499,570

(22) Filed: Nov. 1, 2023

(30) Foreign Application Priority Data
May 4, 2023 (KR) 10-2023-0058089

(51) Int. Cl. H01L 27/146

(52) U.S. Cl. CPC H01L 27/14621; H01L 27/14685

(57) ABSTRACT

Disclosed are image sensing devices. In some implementations, an image sensing device may include a plurality of pixel arrays including first, second, and third pixel arrays, wherein each pixel array comprises a plurality of color filter, and the first pixel array includes a metal grid arranged along an edge of the first pixel array such that the metal grid is disposed between the plurality of color filters in the first pixel array and a plurality of color filters in another pixel array adjacent to the first pixel array, wherein the color filters in the first pixel array are blue color filters.

### PRIORITY CLAIM AND CROSS REFERENCE TO RELATED APPLICATION

This patent document claims the priority and benefits of Korean Patent Application No. 10-2023-0058089, filed on May 4, 2023, which is incorporated by reference in its entirety as part of the disclosure of this patent document.

### TECHNICAL FIELD

Various embodiments of the disclosed technology relate to an image sensing device and a method for manufacturing the same, more specifically, to an image sensing device improving a signal-to-noise ratio (SNR) and a method for manufacturing the same.

### BACKGROUND

An image sensing device refers to a semiconductor device that captures and converts an optical image to electrical signals. With the development of automobile, medical, computer and telecommunication industries, the demand for high-performance image sensing devices is increasing in various devices such as smart phones, digital cameras, game devices, Internet of Things, robots, security cameras, and medical micro-cameras.

The most common types of image sensing devices are charge coupled device (CCD) image sensing devices and complementary metal oxide semiconductor (CMOS) image sensing devices (CIS).

CCD image sensing devices offer a better image quality and generate less noise compared to CMOS image sensing devices. However, CMOS image sensing devices are now widely used due to certain advantages over CCD image sensing devices, including, e.g., various scanning modes. Also, CMOS image sensing devices and signal processing circuitry can be integrated into a single chip, making it possible to fabricate a small-sized image sensing device while achieving a low a production cost. Such characteristics of the CMOS image sensing devices make these devices better suited for implementations in mobile devices.

### SUMMARY

The disclosed technology can be implemented in some embodiments to provide an image sensing device capable of reducing or minimizing crosstalk components that occur due to light rays at a long wavelength and a method of manufacturing the same.

In an embodiment of the disclosed technology, an image sensing device may include a plurality of pixel arrays including first, second, and third pixel arrays, wherein each pixel array comprises a plurality of color filter, and the first pixel array includes a metal grid arranged along an edge of the first pixel array such that the metal grid is disposed between the plurality of color filters in the first pixel array and a plurality of color filters in another pixel array adjacent to the first pixel array, wherein the color filters in the first pixel array are blue color filters.

The first pixel array may include an air grid formed between the blue color filters in the first pixel array.

The second pixel array may include a plurality of green color filters, the third pixel array may include a plurality of red color filters, and an air grid may be formed between the second pixel array and the third pixel array.

The second pixel array may include an air grid formed between the green color filters.

The third pixel array may include an air grid formed between the red color filters.

At least part of the metal grid may be formed between the first pixel array and the second pixel array.

In an embodiment of the disclosed technology, an image sensing device may include: a first pixel array including a plurality of blue color filters; a second pixel array including a plurality of green color filters; and a third pixel array including a plurality of red color filters, a metal grid may be only formed in an edge area of the first pixel array, and an air grid may be formed in an inner area of the first pixel array.

The first pixel array may include a plurality of first unit pixels, the second pixel array may include a plurality of second unit pixels, the third pixel array may include a plurality of third unit pixels, and at least part of the air grid may be formed between the first unit pixels, between the second unit pixels, and between the third unit pixels.

At least part of the air grid may be formed between the second pixel array and the third pixel array.

The metal grid may include: a barrier metal layer; a metal layer formed on the barrier metal layer; and a capping layer formed over the barrier metal layer and the metal layer.

The air grid may include: a barrier metal layer; a supporting layer; an air layer formed between the barrier metal layer and the supporting layer; and a capping layer formed over the barrier metal layer, the air layer, and the supporting layer.

In an embodiment of the disclosed technology, a method for manufacturing an image sensing device may include: forming an edge metal grid over a portion of the substrate corresponding to the first pixel array along an edge of the first pixel array; forming an internal air grid over the portion of the substrate corresponding to the first pixel array, the internal air grid structured to divide a space surrounded by the edge metal grid; and forming a blue color filter between the edge metal grid and the internal air grid.

The forming of the edge metal grid may include: forming barrier metal layers at a certain interval over the substrate corresponding to the first pixel array; and forming metal layers on at least one of the barrier metal layers corresponding to the first pixel array.

The forming of the internal air grid may include: forming a coating layer in an area between the edge metal grids; forming a supporting layer over the edge metal grid and the coating layer; etching an area between the barrier metal layers; forming a capping layer; and removing the coating layer between the edge metal grids.

In an embodiment of the disclosed technology, an image sensing device may include a plurality of pixel arrays including first, second, and third pixel arrays, each pixel array comprising: a plurality of photodetectors configured to detect incident light to output electrical signals indicative of an image of the incident light; and a plurality of color filters respectively disposed over the plurality of photodetectors to filter incident light, wherein the first pixel array includes a metal grid arranged along an edge of the first pixel array such that the metal grid is disposed between the plurality of color filters in the first pixel array and a plurality of color filters in another pixel array adjacent to the first pixel array, wherein the color filters in the first pixel array are blue color filters.

In some implementations, the first pixel array comprises an air grid formed between the blue color filters in the first pixel array.

In some implementations, the second pixel array includes: a plurality of green color filters respectively disposed over a plurality of photodetectors in the second pixel array, and the third pixel array includes: a plurality of red color filters respectively disposed over a plurality of photodetectors in the third pixel array.

In some implementations, the second pixel array comprises an air grid formed between the green color filters.

In some implementations, the third pixel array comprises an air grid formed between the red color filters.

In some implementations, at least part of the metal grid is formed between the first pixel array and the second pixel array.

In an embodiment of the disclosed technology, an image sensing device may include a first pixel array comprising a plurality of first photodetectors, a plurality of blue color filters respectively disposed over the plurality of first photodetectors, and a metal grid arranged along an edge of the first pixel array; a second pixel array comprising a plurality of second photodetectors and a plurality of green color filters respectively disposed over the plurality of second photodetectors; and a third pixel array comprising a plurality of third photodetectors and a plurality of red color filters respectively disposed over the plurality of third photodetectors, wherein the first, second, and third pixel arrays include an air grid arranged between the blue color filters, between the green color filters, and between the red color filters.

In some implementations, the first pixel array comprises a plurality of first unit pixels, each first unit pixel including one of the plurality of first photodetectors and one of the plurality of blue color filters, the second pixel array comprises a plurality of second unit pixels, each second unit pixel including one of the plurality of second photodetectors and one of the plurality of green color filters, the third pixel array comprises a plurality of third unit pixels, each third unit pixel including one of the plurality of third photodetectors and one of the plurality of red color filters, and at least part of the air grid is formed between the first unit pixels, between the second unit pixels, and between the third unit pixels.

In some implementations, at least part of the air grid is formed between the second pixel array and the third pixel array.

In some implementations, the metal grid comprises: a barrier metal layer; a metal layer formed on the barrier metal layer; and a capping layer formed over the barrier metal layer and the metal layer.

In some implementations, the air grid comprises: another barrier metal layer; a supporting layer; an air layer formed between the barrier metal layer and the supporting layer; and a capping layer formed over the barrier metal layer, the air layer, and the supporting layer.

In an embodiment of the disclosed technology, a method for manufacturing an image sensing device may include forming a first pixel array comprising a plurality of first photodetectors, a second pixel array comprising a plurality of second photodetectors, and a third pixel array comprising a plurality of third photodetectors in a substrate; forming an edge metal grid over a portion of the substrate corresponding to the first pixel array along an edge of the first pixel array; forming an internal air grid over the portion of the substrate corresponding to the first pixel array, wherein the internal air grid is formed to divide a space surrounded by the edge metal grid; and forming a blue color filter between the edge metal grid and the internal air grid.

In some implementations, the forming the edge metal grid comprises: forming barrier metal layers at a certain interval over the substrate corresponding to the first pixel array; forming metal layers on at least one of the barrier metal layers corresponding to the first pixel array; and forming capping layers over the metal layers.

In some implementations, the forming the internal air grid comprises: forming barrier metal layers at a certain interval over the substrate corresponding to the first, second, and third pixel arrays; forming a coating layer on at least one of the barrier metal layers corresponding to the second and third pixel arrays such that the coating layer overs an area between the edge metal grids; forming a supporting layer over the coating layer; etching the area between the barrier metal layers such that a portion of the coating layer and a portion of the supporting layer over the barrier metal layers corresponding to the second and third pixel arrays remains; forming a capping layer by forming an additional layer that extends from the portion of the supporting layer over the barrier metal layers corresponding to the second and third pixel arrays such that the additional layer is formed along a side surface of the barrier metal layers corresponding to the second and third pixel arrays; and removing the coating layer disposed between the barrier metal layers and the supporting layer.

In an embodiment of the disclosed technology, an image sensing device may include a plurality of pixel arrays including first, second, and third pixel arrays, each pixel array comprising: a plurality of photodetectors configured to detect incident light to output electrical signals indicative the detected incident light; and a plurality of color filters respectively disposed over the plurality of photodetectors to respectively filter incident light that is detected by the plurality of photodetectors, wherein the first pixel array includes a metal grid arranged along an edge of the first pixel array such that the metal grid is disposed between the plurality of color filters in the first pixel array and a plurality of color filters in another pixel array adjacent to the first pixel array, wherein the color filters in the first pixel array are blue color filters.

In an embodiment of the disclosed technology, an image sensing device may include a first pixel array comprising a plurality of first photodetectors, a plurality of blue color filters respectively disposed over the plurality of first photodetectors, and a metal grid arranged along an edge of the first pixel array; a second pixel array comprising a plurality of second photodetectors and a plurality of green color filters respectively disposed over the plurality of second photodetectors; and a third pixel array comprising a plurality of third photodetectors and a plurality of red color filters respectively disposed over the plurality of third photodetectors, wherein the first, second, and third pixel arrays include an air grid arranged between the blue color filters, between the green color filters, and between the red color filters.

In an embodiment of the disclosed technology, a method for manufacturing an image sensing device may include forming a first pixel array comprising a plurality of first photodetectors, a second pixel array comprising a plurality of second photodetectors, and a third pixel array comprising a plurality of third photodetectors in a substrate; forming an edge metal grid over a portion of the substrate corresponding to the first pixel array along an edge of the first pixel array; forming an internal air grid over the portion of the substrate corresponding to the first pixel array, the internal air grid structured to divide a space surrounded by the edge metal grid; and forming a blue color filter between the edge metal grid and the internal air grid.

### BRIEF DESCRIPTION OF THE DRAWINGS

FIG. 1 is a block diagram illustrating an example of an image sensing device based on an embodiment of the disclosed technology.

FIG. 2 shows an example of a pixel array structure of an image sensing device based on an embodiment of the disclosed technology.

FIG. 3 is a cross-sectional view taken along a sectional line A-A′ of an image sensing device in FIG. 2 based on an embodiment of the disclosed technology.

FIG. 4 is a cross-sectional view taken along a sectional line B-B′ of an image sensing device in FIG. 2 based on an embodiment of the disclosed technology.

FIG. 5 is a flowchart of a method for manufacturing an image sensing device based on an embodiment of the disclosed technology.

FIG. 6 is another flowchart of a method for manufacturing an image sensing device based on an embodiment of the disclosed technology.

FIG. 7 is another flowchart of a method for manufacturing an image sensing device based on an embodiment of the disclosed technology.

FIGS. 8 to 12 show a method for manufacturing an image sensing device based on some embodiments of the disclosed technology.

### DETAILED DESCRIPTION

Features, and certain advantages in connection with specific implementations of the disclosed technology disclosed in this patent document are described by example embodiments with reference to the accompanying drawings.

A signal-to-noise ratio (SNR) of an image sensing device can be derived based on signal and noise in an image to which a color correction matrix (CCM) is applied. The CCM includes a 3×3 matrix, and each element of the CCM except for diagonal elements corresponds to a crosstalk of each element.

However, a crosstalk in an air grid structure disposed in the image sensing device that occurs due to light rays at a long wavelength may lead to SNR deterioration.

The crosstalk may include spectral crosstalk due to limitations in color filters, spatial crosstalk, and an electrical crosstalk.

In order to enhance SNR, of the crosstalk components of the CCM, a green crosstalk component that occurs at a blue light wavelength due to a green light wavelength, and a blue crosstalk component that occurs at a green light wavelength should be improved. In some implementations, a signal-to-noise ratio (SNR) may be improved by reducing or minimizing the crosstalk of each component of the CCM. In some implementations, a signal-to-noise ratio (SNR) may be improved by reducing or minimizing a green crosstalk component that occurs at a blue light wavelength and a blue crosstalk component that occurs at a green light wavelength.

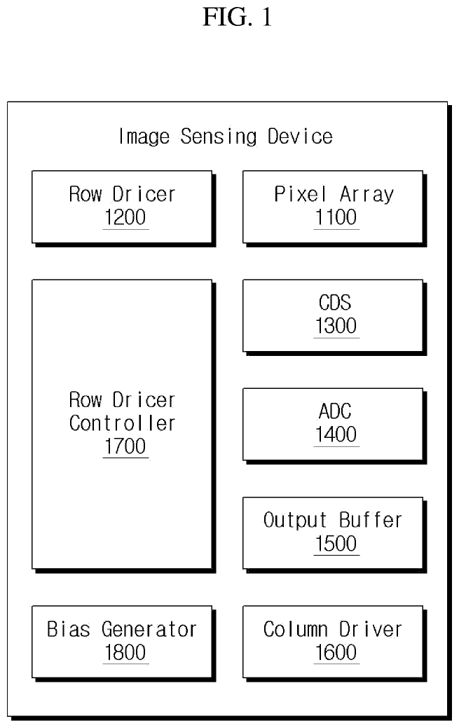

FIG. 1 is a block diagram illustrating an image sensing device based on an embodiment of the disclosed technology.

Referring to FIG. 1, an image sensing device based on an embodiment of the disclosed technology includes a pixel array 1100, a row driver 1200, a correlated double sampler (CDS) 1300, an analog-to-digital converter (ADC) 1400, an output buffer 1500, a column driver 1600, a timing controller 1700, and a bias generator 1800. The above-mentioned constituent elements of the image sensing device are listed by way of example only, and thus at least some of the above-mentioned constituent elements of the image sensing device may be omitted and an additional constituent element may be added to the image sensing device.

The pixel array 1100 may include a plurality of pixels arranged in a plurality of rows and a plurality of columns. In one example, the plurality of pixels can be arranged in a two-dimensional pixel array including rows and columns. In another example, the plurality of pixels can be arranged in a three-dimensional pixel array. The plurality of pixels may convert an optical signal into an electrical signal on a unit pixel basis or a pixel group basis, where pixels in a pixel group share at least certain internal circuitry. The pixel array 1100 may receive driving signals, including a row selection signal, a pixel reset signal and a transmission signal, from the row driver 1200. Upon receiving the driving signal, corresponding pixels in the pixel array 1100 may be activated to perform the operations corresponding to the row selection signal, the pixel reset signal, and the transmission signal.

The row driver 1200 may activate the pixel array 1100 to perform certain operations on the pixels in the corresponding row based on commands and control signals provided by the timing controller 1700. In an embodiment, the row driver 1200 may select one or more pixels arranged in one or more rows of the pixel array 1100. The row driver 1200 may generate a row selection signal to select at least one or more rows of the plurality of rows. The row driver 1200 may sequentially enable the transmission signal and the pixel reset signal for resetting pixels corresponding to at least one selected row. Thus, an analog reference signal and an analog image signal generated by each of the imaging pixels of the selected row may be sequentially transferred to the CDS 1300. Here, the reference signal may be an electrical signal that is provided to the CDS 1300 when a sensing node of a pixel (e.g., floating diffusion node) is reset, and the image signal may be an electrical signal that is provided to the CDS 1300 when photocharges generated by the pixel are accumulated in the sensing node. The reference signal representing reset noise inherent in the pixel and the image signal representing intensity of incident light may be collectively referred to as a pixel signal.

CMOS image sensors may use the correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments, the CDS 1300 may sequentially sample and hold voltage levels of the reference signal and the image signal, which are provided to each of a plurality of column lines from the pixel array 1100. That is, the CDS 1300 may sample and hold the voltage levels of the reference signal and the image signal which correspond to each of the columns of the pixel array 1100.

The CDS 1300 may transfer the reference signal and the image signal of each of the columns as a correlate double sampling signal to the ADC 1400 based on control signals from the timing controller 1700.

The ADC 1400 may convert analog CDS signals of each of the columns output from the CDS 1300 into digital signals and output the digital signals. In some embodiments, the ADC 1400 may be implemented as a ramp-compare type ADC. The ramp-compare type ADC may include a comparator circuit for comparing the analog pixel signal with a reference signal such as a ramp signal that ramps up or down, and a timer counts until a voltage of the ramp signal matches the analog pixel signal. In some embodiments, the ADC 1400 may convert the correlate double sampling signal generated by the CDS 1300 for each of the columns into a digital signal, and output the digital signal.

The ADC 1400 may include a plurality of column counters corresponding to each of the columns of the pixel array 1100. Each column of the pixel array 1100 is coupled to a column counter, and image data can be generated by converting the correlate double sampling signals received from each column into digital signals using the column counter. In another embodiment, the ADC 1400 may include a global counter to convert the correlate double sampling signals corresponding to the columns into digital signals using a global code provided from the global counter.

The output buffer 1500 may temporarily hold the column-based image data provided from the ADC 1400 to output the image data. The output buffer 1500 may temporarily store the image data from the ADC 1400 based on control signals of the timing controller 1700. The output buffer 1500 may operate as an interface that compensates for a difference in transmission (or processing) speed between the image sensing device and other connected devices.

The column driver 1600 may select a column of the output buffer upon receiving a control signal from the timing controller 1700, and sequentially output the image data, which are temporarily stored in the selected column of the output buffer 1500. In an embodiment, the column driver 1600 may receive an address signal from the timing controller 1700, the column driver 1600 may generate a column selection signal based on the address signal and select a column of the output buffer 1500, outputting the image data as an output signal from the selected column of the output buffer 1500.

The timing controller 1700 may control at least one among the row driver 1200, the CDS 1300, the ADC 1400, the output buffer 1500, the column driver 1600, and the bias generator 1800.

The timing controller 1700 may provide at least one among the row driver 1200, the CDS 1300, the ADC 1400, the output buffer 1500, the column driver 1600 and the bias generator 1800 with a clock signal required for the operations of the respective components of the image sensing device, a control signal for timing control, address signals for selecting a row or column, and a signal that controls a level of a bias voltage applied to the pixel array 1100. In an embodiment of the disclosed technology, the timing controller 1700 may include a logic control circuit, a phase lock loop (PLL) circuit, a timing control circuit, and a communication interface circuit, and the like.

The bias generator 1800 may generate a bias voltage for suppressing dark current generated in pixels of the pixel array 1100 and may provide the generated bias voltage to the pixel array 1100.

The bias voltage may be decided in a wafer probe test process and stored in a one-time programmable (OTP) memory. For example, the bias voltage may be experimentally determined as a value capable of maximizing a dark current suppression effect while minimizing unnecessary power consumption without impairing performance of the image sensing device.

The bias generator 1800 may generate a voltage corresponding to the bias voltage value stored in an OTP memory. In an embodiment of the disclosed technology, the OTP memory may be included in the image sensing device. In one example, the OTP memory may be included in the bias generator 1800.

In an embodiment of the disclosed technology, the bias voltage may include a plurality of values.

In one example, the plurality of values of the bias voltage may respectively correspond to a plurality of operation modes of the image sensing device. A dark current generated at low-intensity light and a dark current generated at high-intensity light may be different from each other, and a bias voltage, which is provided by the bias generator 1800 to effectively suppress dark current in each environment, may vary depending on the operation mode of the image sensing device.

In another example, the plurality of values of the bias voltage may respectively correspond to a plurality of regions of the pixel array 1100. The dark current may vary depending on the position of the corresponding pixel on the pixel array 1100, and the bias voltage, which is provided by the bias generator 1800 to effectively suppress the dark current regardless of a position of the pixel, may vary depending on the region of the pixel array 1100.

The bias voltage may be a may be a negative (−) voltage, but the disclosed technology is not limited thereto.

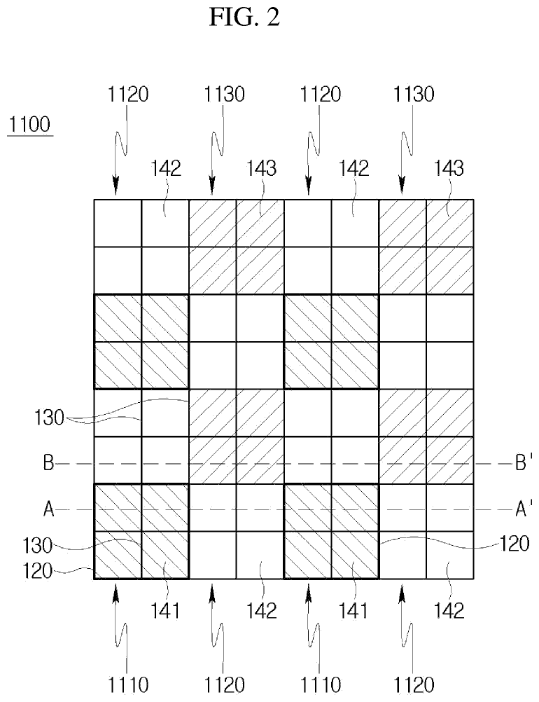

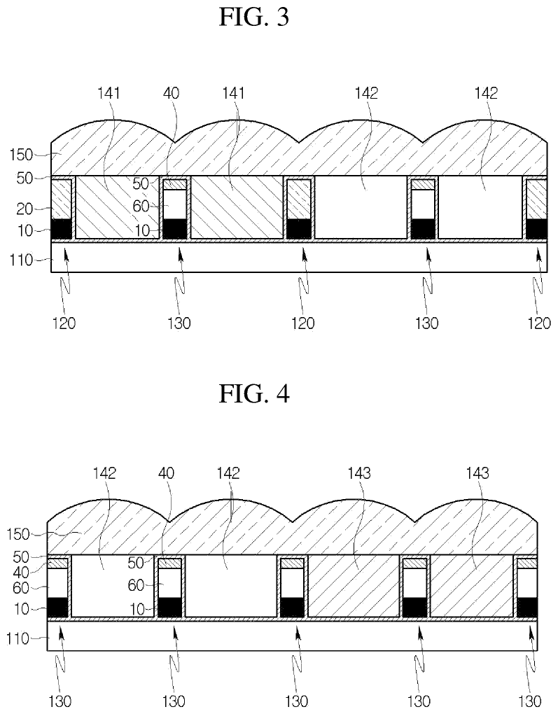

FIG. 2 shows an example of a pixel array structure of an image sensing device based on an embodiment of the disclosed technology. FIG. 3 is a cross-sectional view taken along a sectional line A-A′ of an image sensing device in FIG. 2 based on an embodiment of the disclosed technology. FIG. 4 is a cross-sectional view taken along a sectional line B-B′ of an image sensing device in FIG. 2 based on an embodiment of the disclosed technology.

Referring to FIGS. 2 and 3, the image sensing device based on an embodiment of the disclosed technology may include a plurality of pixel arrays 1100.

Each pixel array 1100 may include a substrate 110, a photodetector such as a photodiode (not illustrated) disposed in the substrate 110, color filters 141, 142 and 143 disposed over the substrate, which includes the photodetectors, and microlenses 150.

The substrate 110 may include single-crystalline silicon (Si) material.

The photodiode (not illustrated) may be formed in the substrate 110. In some implementations, an upper surface of the photodiode can be exposed through an upper surface of the substrate 110. In some implementations, the photodiode (not illustrated) may include an N-type impurity region and a P-type impurity region that are stacked. The N-type impurity region and the P-type impurity region may be formed through an ion implantation process.

The color filters may be formed over the substrate 110 (e.g., over the photodiode). The color filters may filter visible light from the incident light received through the microlens 150 so that visible light at a desired wavelength can reach the photodiode. In some implementations, the color filter may include a blue color filter 141 that transmits only blue light, a green color filter 142 that transmits only green light, and a red color filter 143 that transmits only red light. The microlenses may be formed on the color filters 141, 142 and 143, may converge incident light and may transmit the light to the color filters 141, 142 and 143.

The plurality of pixel arrays 1100 may include a first pixel array 1110 corresponding to a blue pixel array including the blue color filter 141, a second pixel array 1120 corresponding to a green pixel array including the green color filter 142, and a third pixel array 1130 corresponding to a red pixel array including the red color filter 143.

In an embodiment, of the plurality of pixel arrays 1100, only the first pixel array 1110 includes a metal grid 120 in an edge area of the first pixel array 1110 that includes the blue color filter 141.

In an embodiment, the metal grid 120 may include a barrier metal layer 10, a metal layer 20, and a capping layer 50.

In an embodiment, the barrier metal layer 10 may include titanium nitride (TiN) layer.

In an embodiment, the metal layer 20 may be formed on the barrier metal layer 10, and may include tungsten (W).

In an embodiment, the capping layer 50 may be formed over the barrier metal layer 10 and the metal layer 20, and may include an ultra-low temperature oxide (ULTO) layer.

In an embodiment, the metal grid 120 may be formed between the first pixel array 1110 and the second pixel array 1120.

Since the metal grid 120 is formed only in an edge area of the blue pixel array and is not formed in the green or red pixel arrays, a crosstalk that occurs due to light rays at a long wavelength may be reduced or minimized. Specifically, the disclosed technology can be implemented in some embodiments to reduce or minimize a green crosstalk component at the blue light wavelength.

An air grid 130 may be formed in an inner area of the first pixel array 1110.

In some implementations, the air grid 130 can be used reduce or minimize the blue crosstalk component at the green wavelength.

In an embodiment, the air grid 130 may include the barrier metal layer 10, the supporting layer 40, the air layer 60, and the capping layer.

In an embodiment, the barrier metal layer 10 may include a titanium nitride (TiN) layer.

In an embodiment, the supporting layer 40 may include at least one of a silicon oxynitride (SiON) layer, silicon oxide (SiO) layer, or silicon nitride (SiN) layer.

In an embodiment, the air layer 60 may be formed between the barrier metal layer 10 and the supporting layer 40.

In an embodiment, the capping layer 50 may be formed over the barrier metal layer 10, the air layer 60, and the supporting layer 40, and may include an ultra-low temperature oxide (ULTO) layer.

The first pixel array 1110 may include a plurality of first unit pixels, and the air grid 130 may be formed between the first unit pixel and the first unit pixel.

In an embodiment, each of the first unit pixels includes the blue color filter 141, and the air grid 130 may be formed between the blue color filter 141 and the blue color filter 141.

Referring to FIGS. 2 and 4, in some embodiments of the disclosed technology, the air grid 130 may be formed between the second pixel array 1120 including the green color filter 142 and the third pixel array 1130 including the red color filter 143.

The air grid 130 may be formed in an inner area of the second pixel array 1120.

The second pixel array 1120 may include a plurality of second unit pixels, and the air grid 130 may be formed between the second unit pixel and the second unit pixel.

In an embodiment, each of the second unit pixels includes the green color filter 142, and the air grid 130 may be formed between the green color filter 142 and the green color filter 142.

The air grid 130 may be formed in an inner area of the third pixel array 1130.

The third pixel array 1130 may include a plurality of third unit pixels, and the air grid 130 may be formed between the third unit pixel and the third unit pixel.

In an embodiment, each of the third unit pixels includes the red color filter 143, and the air grid 130 may be formed between the red color filter 143 and the red color filter 143.

In an embodiment, the air grid is formed between the second pixel array 1120 including the green color filter 142 and the third pixel array 1130 including the red color filter 142, between the green color filter 142 and the green color filter 142, and between the red color filter 143 and the red color filter 143, and may include the barrier metal layer 10, the supporting layer 40, the air layer 60, and the capping layer.

In an embodiment, the barrier metal layer 10 may include a titanium nitride (TiN) layer.

In an embodiment, the supporting layer 40 may include at least one of a silicon oxynitride (SiON) layer, silicon oxide (SiO) layer, or silicon nitride (SiN) layer.

In an embodiment, the air layer 60 may be formed between the barrier metal layer 10 and the supporting layer 40.

In an embodiment, the capping layer 50 may be formed over the barrier metal layer 10, the air layer 60, and the supporting layer 40, and may include an ultra-low temperature oxide (ULTO) layer.

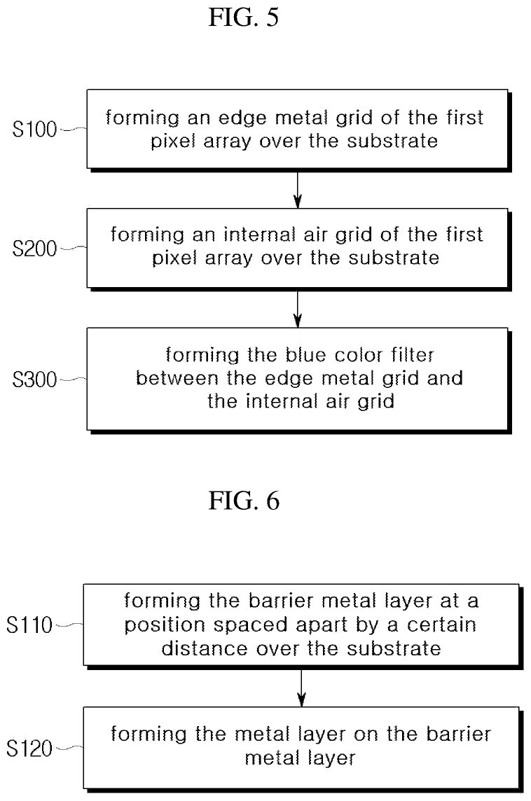

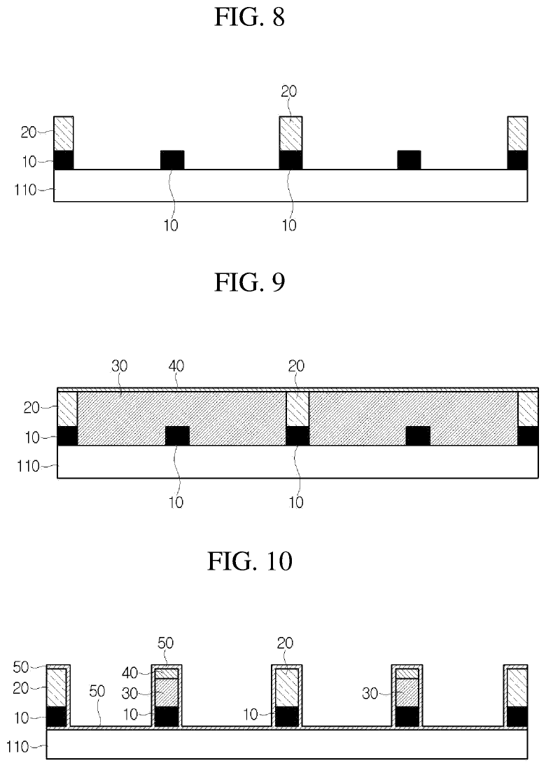

FIGS. 5 to 7 are flowcharts of a method for manufacturing the image sensing device based on some embodiments of the disclosed technology. FIGS. 8 to 12 show a method for manufacturing the image sensing device based on an embodiment of the disclosed technology.

Referring to FIG. 5, a method for manufacturing an image sensing device may include: forming an edge metal grid 120 of the first pixel array 1110 over the substrate 110 (S100); forming an internal air grid 130 of the first pixel array 1110 over the substrate 110 (S200); and forming the blue color filter between the edge metal grid 120 and the internal air grid 130 (S300).

Referring to FIG. 6, the forming of the edge metal grid 120 (S100) may include forming the barrier metal layer 10 at a position spaced apart by a certain distance over the substrate 110 (S110); and forming the metal layer 20 on the barrier metal layer 10 (S120).

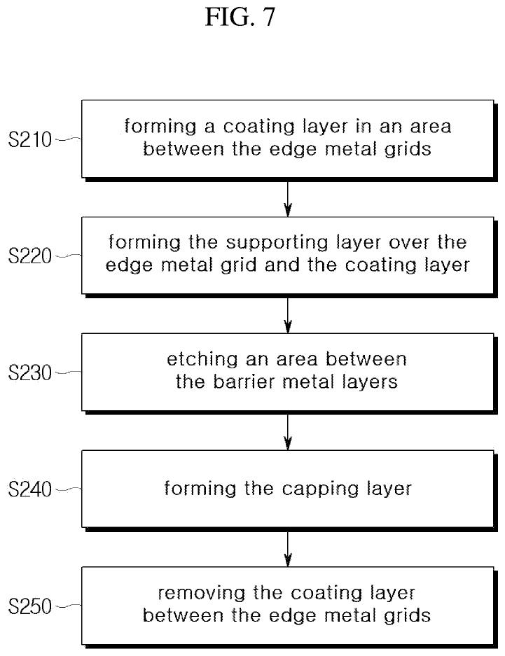

Referring to FIG. 7, forming an internal air grid 130 (S200) may include: forming a coating layer 30 in an area between the edge metal grids (S210); forming the supporting layer 40 over the edge metal grid 120 and the coating layer 30 (S220); etching an area between the barrier metal layers 10 (S230); forming the capping layer 50 (S240); and removing the coating layer 30 between the edge metal grids 120 (S250).

Referring to FIG. 8, in the forming of the barrier metal layer 10 (S110), the barrier metal layer 10 may be formed through a deposition process of the titanium nitride (TiN) layer at a position spaced apart by a certain distance over the substrate 110.

In the forming of the metal layer 20 on the barrier metal layer 10 (S120), the metal layer 20 may be formed on the barrier metal layer 10 through a deposition process of tungsten (W).

Referring to FIG. 9, in the forming of a coating layer 30 (S210), the coating layer 30 may be formed in an area between the edge metal grids 120. The coating layer 30 may include spin-on carbon (SOC).

In the forming of the supporting layer 40 (S220), the supporting layer 40 may be formed to support the capping layer 50 over the edge metal grid 120 and the coating layer 30. In an embodiment, the supporting layer 40 may include at least one of a silicon oxynitride (SiON) layer, silicon oxide (SiO) layer, or silicon nitride (SiN) layer.

Referring to FIG. 10, in the etching of the area between the barrier metal layers 10 (S230), an air grid structure may be formed between the edge metal grid 120 and the edge metal grid 120, by etching the coating layer 30 and the supporting layer 40 in an area between the barrier metal layers 10 using an etch mask.

In an embodiment, the etching process may be performed through one of high-density plasma oxidation processes such as ICP (Inductively Coupled Plasma), DPS (Decoupled Plasma Source), or ECR (Electron Cyclotron Resonance), a remote insitu oxidation process, and a process of forming a laminate structure by combining compounds of III-IV groups.

In the forming of the capping layer 50 (S240), the capping layer 50 may be formed through a deposition process of an ultra-low temperature oxide (ULTO) layer over the barrier metal layer 10, the metal layer 20, the supporting layer 40, and the substrate 110, after etching.

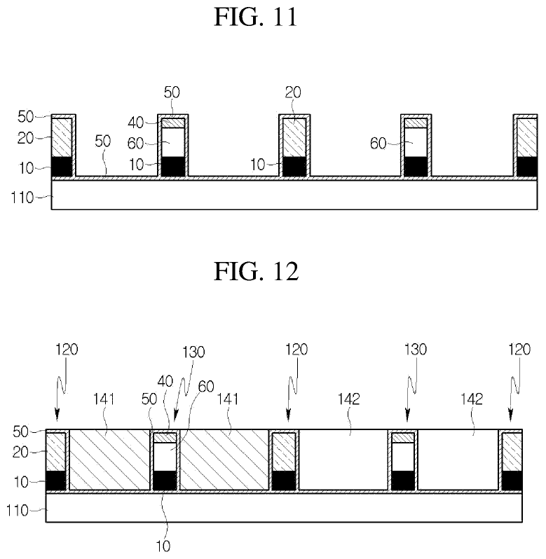

Referring to FIG. 11, in the removing the coating layer 30 between the edge metal grids 120 (S250), the air layer 60 may be formed by removing the coating layer 30 between the supporting layer 40 and the barrier metal layer 10 of the air grid structure through an O2 plasma process.

Referring to FIG. 12, in the forming of a blue color filter (S300), color filters 141, 142 and 143 may be formed between the edge metal grid 120 and the internal air grid 130.

In some implementations, it is possible to reduce a crosstalk component that occurs due to light rays at a short wavelength by means of the air grid structure, and yet the crosstalk component at the long wavelength may be deteriorated. In order to improve SNR, a crosstalk component of the green pixel at a blue light wavelength and a crosstalk component of the blue pixel at a green light wavelength may be improved.

In some embodiments of the disclosed technology, by forming the metal grid 120 only in the edge area of the blue pixel in the entire air grid 130 structure, it is possible to reduce or minimize a crosstalk component that occurs due to light rays at a long wavelength, as well as a crosstalk component that occurs due to light rays at a short wavelength.

In addition, by forming the metal grid 120 only in the edge area of the blue pixel in the entire air grid 130 structure, a crosstalk component of the green pixel that occurs due to light rays at a blue wavelength and a crosstalk component of the blue pixel that occurs due to light rays at a green wavelength may be reduced or minimized, thereby improving the signal-to-noise ratio (SNR).

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples of the disclosed technology are described and other implementations, enhancements and variations can be made based on what is described and illustrated in this patent document.

What is claimed is:

1. An image sensing device, comprising:
a plurality of pixel arrays including first, second, and third pixel arrays,
wherein each pixel array comprises a plurality of color filter, and
the first pixel array includes a metal grid arranged along an edge of the first pixel array such that the metal grid is disposed between the plurality of color filters in the first pixel array and a plurality of color filters in another pixel array adjacent to the first pixel array, wherein the color filters in the first pixel array are blue color filters.

2. The image sensing device of claim 1,
wherein the first pixel array comprises an air grid formed between the blue color filters in the first pixel array.

3. The image sensing device of claim 2,
wherein the second pixel array includes a plurality of green color filters, and
the third pixel array includes a plurality of red color filters,
wherein an air grid is formed between the second pixel array and the third pixel array.

4. The image sensing device of claim 3,
wherein the second pixel array comprises an air grid formed between the green color filters.

5. The image sensing device of claim 3,
wherein the third pixel array comprises an air grid formed between the red color filters.

6. The image sensing device of claim 3,
wherein at least part of the metal grid is formed between the first pixel array and the second pixel array.

7. An image sensing device, comprising:
a first pixel array comprising a plurality of blue color filters;
a second pixel array comprising a plurality of green color filters; and
a third pixel array comprising a plurality of red color filters,
wherein a metal grid is formed only in an edge area of the first pixel array, and
an air grid is formed in an inner area of the first pixel array.

8. The image sensing device of claim 7,
wherein the first pixel array comprises a plurality of first unit pixels,
the second pixel array comprises a plurality of second unit pixels,
the third pixel array comprises a plurality of third unit pixels, and
wherein at least part of the air grid is formed between the first unit pixels, between the second unit pixels, and between the third unit pixels.

9. The image sensing device of claim 8,
wherein at least part of the air grid is formed between the second pixel array and the third pixel array.

10. The image sensing device of claim 8,
wherein the metal grid comprises:
a barrier metal layer;
a metal layer formed on the barrier metal layer; and
a capping layer formed over the barrier metal layer and the metal layer.

11. The image sensing device of claim 8,
wherein the air grid comprises:
a barrier metal layer;
a supporting layer;
an air layer formed between the barrier metal layer and the supporting layer; and
a capping layer formed over the barrier metal layer, the air layer, and the supporting layer.

12. A method for manufacturing an image sensing device, comprising:
forming an edge metal grid over a portion of a substrate corresponding to a first pixel array along an edge of the first pixel array;
forming an internal air grid over the portion of the substrate corresponding to the first pixel array, wherein the internal air grid is formed to divide a space surrounded by the edge metal grid; and
forming a blue color filter between the edge metal grid and the internal air grid.

13. The method of claim 12, wherein the forming the edge metal grid comprises:
forming barrier metal layers at a certain interval over the substrate corresponding to the first pixel array; and
forming metal layers on at least one of the barrier metal layers corresponding to the first pixel array.

14. The method of claim 13, wherein the forming the internal air grid comprises:
forming a coating layer in an area between the edge metal grids;
forming a supporting layer over the edge metal grid and the coating layer;
etching an area between the barrier metal layers;
forming a capping layer; and
removing the coating layer between the edge metal grids.
